(19) United States
(12) Patent Application Publication
(10) Pub. No.: US 2026/0085898 A1
(43) Pub. Date: Mar. 26, 2026

(54) DUAL MODE HEATSINK

(71) Applicant: Raytheon Systems Limited, Harlow (GB)

(72) Inventor: David L. Gordon, Kirkcaldy (GB)

(21) Appl. No.: 19/404,705

(22) Filed: Dec. 1, 2025

Related U.S. Application Data
(63) Continuation of application No. PCT/GB2024/051449, filed on Jun. 5, 2024.

(30) Foreign Application Priority Data
Jun. 14, 2023 (GB) 2308863

(51) Int. Cl. F28F 3/12; F28D 21/00; F28F 3/04; F28F 21/08

(52) U.S. Cl. CPC F28F 3/12; F28F 3/04; F28F 21/08; F28D 2021/0029; F28F 2215/00

(57) ABSTRACT

A dual mode heatsink includes a base comprising a first surface arranged to receive heat energy from a heat source and a second surface; and cooling fins attached to and extending from the second surface; wherein the base further comprises at least one liquid channel arranged between the first surface and the second surface, the at least one liquid channel being defined by one or more walls forming a heat conducting connection between the first surface and the second surface.

### CROSS-REFERENCE TO RELATED APPLICATION AND PRIORITY CLAIM

This application claims priority as a continuation of International Patent Application No. PCT/GB2024/051449 filed on Jun. 5, 2024, which claims priority to United Kingdom Patent Application No. GB2308863.6 filed on Jun. 14, 2023. Both of these applications are hereby incorporated by reference in their entirety.

### FIELD OF THE INVENTION

The present application relates to a dual mode heat sink, and in particular to a dual mode heat sink suitable for either gas or liquid cooling.

### BACKGROUND

Heatsinks are commonly used to provide cooling to heat generating objects, such as electronic and electrical components and devices. There are a number of known types of heatsink using different mechanisms to transport heat energy away from a heat generating object in contact with the heatsink and release the heat energy into the environment, in order to cool the heat generating object.

In practice there is a problem that a large number of different designs of heatsink are required for different applications, requiring an inventory of a large number of different heatsinks to be maintained for manufacture, repair and maintenance, leading to undesirable expense, and making the logistics of repair and maintenance complex. Further, in safety-critical applications a large number of different heatsink designs must be tested and certified, increasing costs further.

The embodiments described below are not limited to implementations which solve any or all the disadvantages of the known approaches described above.

### SUMMARY

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter; variants and alternative features which facilitate the working of the invention and/or serve to achieve a substantially similar technical effect should be considered as falling into the scope of the invention disclosed herein.

In a first aspect of the present invention, there is provided a dual mode heatsink comprising: a base comprising; a first surface arranged to receive heat energy from a heat source, and a second surface; and cooling fins attached to and extending from the second surface; wherein the base further comprises at least one liquid channel arranged between the first surface and the second surface, the at least one liquid channel being defined by one or more walls forming a heat conducting connection between the first surface and the second surface.

This may provide the advantages of improved flexibility of use of the dual mode heatsink, whereby the same dual mode heatsink may be used in both applications requiring gas cooling and applications requiring liquid cooling. This may reduce the number of different heat sink designs which must be produced, tested and certified, and maintained in inventory for use in manufacturing, repair, and maintenance tasks, thus reducing costs and simplifying logistics.

In a preferred example, the cooling fins define gas flow channels between them. This may provide the advantage of more efficient gas cooling.

In a preferred example, the cooling fins are located across an area of the second surface, and the liquid channels and walls are arranged within the base at locations corresponding to the area of the second surface. This may provide the advantage of improved heat conduction from the heat source to the cooling fins.

In a preferred example, the cooling fins comprise a plurality of parallel fins and the walls extend parallel to the fins. This may provide advantages of ease of manufacture and improved heat conduction from the heat source to the cooling fins.

In a preferred example, the cooling fins have a pitch equal to, or an integer multiple of, a pitch of the walls, and each cooling fin is aligned with a respective wall. This may provide advantages of improved heat conduction from the heat source to the cooling fins and increased structural strength.

In a preferred example, the dual mode heatsink is arranged to be operable in a first, gas cooled, mode in which heat energy is transferred from the dual mode heatsink to gas flowing past the cooling fins, or in a second, liquid cooled mode, in which heat energy is transferred from the dual mode heatsink to liquid flowing through the at least one liquid channel; and the rate of heat transfer to the gas in the first, gas cooled, mode is substantially the same as the rate of heat transfer to the liquid in the second, liquid cooled, mode. This may provide the advantage that the same dual mode heatsink may be used in a particular cooling application regardless of whether gas cooling or liquid cooling is to be used. This may further reduce the number of different heat sink designs which must be produced, tested and certified, and maintained in inventory for use in manufacturing, repair, and maintenance tasks, thus reducing costs and simplifying logistics.

In a preferred example, the at least one liquid channel comprises a plurality of parallel liquid channels. This may provide the advantages of improved efficiency of liquid cooling,

In a preferred example, the base and the cooling fins are integrally formed. This may provide the advantage of improved heat conduction between the heat source and the cooling fins.

In a preferred example, the walls and the first and second surfaces of the base are integrally formed. This may provide the advantages of improved heat conduction between the heat source and the cooling fins and between the heat source and the walls.

In a preferred example, wherein the dual mode heatsink is produced by additive manufacturing. This may provide the advantages of efficient and cheap manufacturing.

In a preferred example, the body and cooling fins comprise aluminum, copper, or alloys thereof. This may provide the advantages of improved heat conduction throughout the heatsink.

In a second aspect of the present invention, there is provided a temperature control system comprising: a dual mode heatsink according to the first aspect; a heat source in thermal contact with the first surface; and at least one of: a gas flow generator arranged to produce a gas flow past the cooling fins; and a liquid flow generator arranged to produce a liquid flow through the at least one liquid channel. This may provide corresponding advantages to the first aspect.

In a preferred example, the system comprises either: a gas flow generator arranged to produce a gas flow past the cooling fins; or a liquid flow generator arranged to produce a liquid flow through the at least one liquid channel. This may provide the advantage that the same dual mode heatsink may be used in a particular cooling application regardless of whether gas cooling or liquid cooling is to be used. This may further reduce the number of different heat sink designs which must be produced, tested and certified, and maintained in inventory for use in manufacturing, repair, and maintenance tasks, thus reducing costs and simplifying logistics.

In a preferred example, the dual mode heatsink is arranged so that the rate of heat transfer to the gas flow is substantially the same as the rate of heat transfer to the liquid flow. This may provide the advantage that the same dual mode heatsink may be used in a particular cooling application regardless of whether gas cooling or liquid cooling is to be used. This may further reduce the number of different heat sink designs which must be produced, tested and certified, and maintained in inventory for use in manufacturing, repair, and maintenance tasks, thus reducing costs and simplifying logistics.

In a preferred example, the gas flow generator comprises a fan. This may provide the advantage of improved gas cooling.

In a preferred example, the gas flow comprises air. This may provide the advantages that air is readily available at low cost.

In a preferred example, the liquid flow generator comprises a pump and a heat exchanger. This may provide the advantages of improved liquid cooling, and allowing a closed liquid circuit to be used.

In a preferred example, the liquid flow comprises water. This may provide the advantages that water is readily available at low cost, and has a high heat capacity to absorb and transport heat energy.

In a third aspect of the present invention, there is provided a method of cooling a heat source, the method comprising: providing a dual mode heatsink according to the first aspect; arranging the first surface of the dual mode heatsink in contact with a heat source; and providing at least one of: a gas flow past the cooling fins; and a liquid flow through the at least one liquid channel. This may provide corresponding advantages to the first aspect.

In a preferred example, the method comprises either: providing a gas flow past the cooling fins; or providing a liquid flow through the at least one liquid channel.

The features and embodiments discussed above may be combined as appropriate, as would be apparent to a person skilled in the art, and may be combined with any of the aspects of the invention except where it is expressly provided that such a combination is not possible or the person skilled in the art would understand that such a combination is self-evidently not possible.

### BRIEF DESCRIPTION OF THE DRAWINGS

Embodiments of the invention will be described, by way of example only and with reference to the following drawings, in which:

FIG. 1 shows a perspective view from above of a dual mode heatsink according to a first embodiment;

FIG. 2 shows a perspective view from below of the dual mode heatsink of FIG. 1;

FIG. 3 shows a partial cross-sectional view along the line A-A in FIG. 1;

FIG. 4 shows a side view of a dual mode heatsink according to a second embodiment;

FIG. 5 shows a cut-away view of the dual mode heatsink of FIG. 4;

FIG. 6 shows a schematic diagram of the dual mode heatsink of FIG. 4 operating in a gas cooled mode; and

FIG. 7 shows a schematic diagram of the dual mode heatsink of FIG. 4 operating in a liquid cooled mode.

### DETAILED DESCRIPTION

Embodiments of the present invention are described below by way of example only. These examples represent the best mode of putting the invention into practice that are currently known to the Applicant although they are not the only ways in which this could be achieved. The description sets forth the functions of the example and the sequence of step for constructing and operating the example. However, the same or equivalent functions and sequences may be accomplished by different examples.

In summary, the present disclosure provides a dual mode heatsink able to provide both liquid-cooling and gas-cooling in the same structure. The ability to use both liquid-cooling and gas-cooling by the same heatsink structure provides improved flexibility of use of the dual mode heatsink.

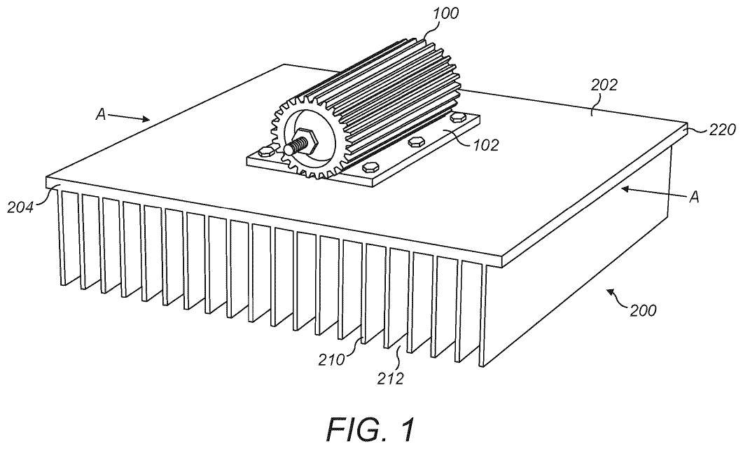

FIG. 1 shows a perspective view from above of a dual mode heatsink 200 according to a first embodiment. The heatsink 200 comprises a base in the form of a base plate 220 having a first surface 202 and a second surface 204 on opposite sides of the base plate 220. The first and second surfaces 202 and 204 are substantially planar and parallel. In the illustrated example of FIG. 1 the first surface 202 faces upward and the second surface 204 faces downward, but this is for convenience of illustration only. The dual mode heatsink 200 may be arranged in any orientation in operation, as necessary.

The first surface 202 of the dual mode heatsink 200 is suitable for a heat source or a heat generating object 100, to be attached to the heatsink 200 in heat conducting contact so that the heatsink 200 can cool the heat generating object 100 by heat energy from the heat generating object 100 travelling by conduction to the heatsink 200 in contact with the heat generating object 100. The heat energy transferred to the heatsink 200 is subsequently transported away from the heatsink 200, as is described in detail below. As shown in FIG. 1, the heatsink 200 and the heat generating object 100 in combination are comprised in a temperature control system which can control the temperature of the heat generating object 100.

In the illustrated example of FIG. 1, the heat generating object 100 is attached to the first surface 202 of the heatsink 200. The heat generating object 100 may be releasably attached to the heatsink 200. In the illustrated example of FIG. 1, the heat generating object 100 is releasably attached to the heatsink 200 via a plurality of bolts 102. Alternatively, in other examples, the heat generating object 100 can be permanently attached to the heatsink 200. For example, the heat generating object 100 can be permanently attached to the heatsink 200 via welding or an adhesive layer. The described means of attachment are examples only, and other releasable or permanent attachment means can be used in alternative examples.

In the illustrated example of FIG. 1, the heat generating object 100 is a power resistor. However, this is by way of example only, and any number of heat sources, such as different types of heat generating device, requiring cooling may be used with the heatsink 200. For example, the heat generating object 100 may be another electrical component, or electrical circuitry, such as a transformer, an amplifier, an integrated circuit or a module or device comprising a plurality of integrated circuits. These examples are not intended to be exhaustive.

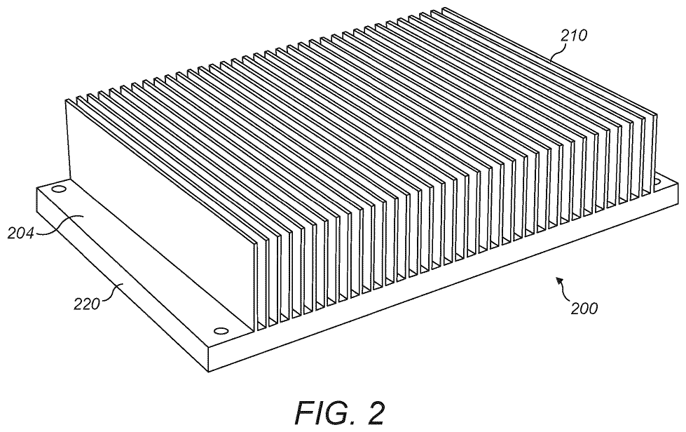

FIG. 2 shows a perspective view from below of the dual mode heatsink 200 according to the first embodiment. The heat generating object 100 is not visible in FIG. 2.

As can be seen in FIGS. 1 and 2, the dual mode heatsink 200 comprises a plurality of cooling fins 210 attached to the second surface 204 of the base plate 220. Accordingly, the base plate 220 may also be referred to a fin base. The cooling fins 210 are each substantially flat and planar, are arranged parallel to one another, and extend perpendicularly to the second surface 204 of the base plate 220. The cooling fins 210 define gas flow channels 212 between them. The cooling fins 210 are located extending across an area of the second surface 204 of the base plate 220.

The illustrated example of FIGS. 1 and 2 has the cooling fins 210 integrally formed with the base plate 220. Conveniently, these integrally formed cooling fins 210 and base plate 220 can be formed by an additive manufacturing technique. In alternative examples, the cooling fins 210 the base plate 220 can be formed from a single solid piece by machining. In other alternative examples, the cooling fins 210 and the base plate 220 can be manufactured as separate parts and subsequently attached together. in such alternative examples, the cooling fins 210 can be attached to the heatsink 200 via welding or a heat conductive adhesive layer.

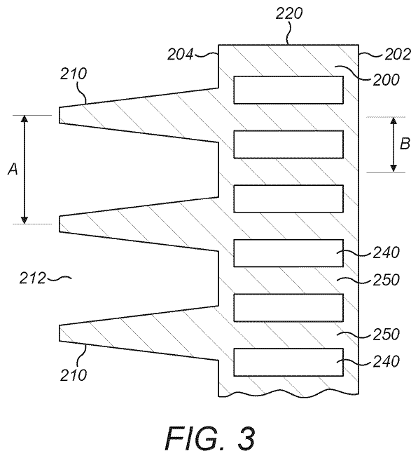

FIG. 3 shows a partial cross-sectional view of the dual mode heatsink 200 according to the first embodiment along the line A-A in FIG. 1.

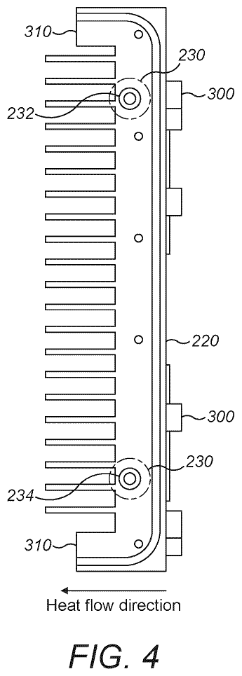

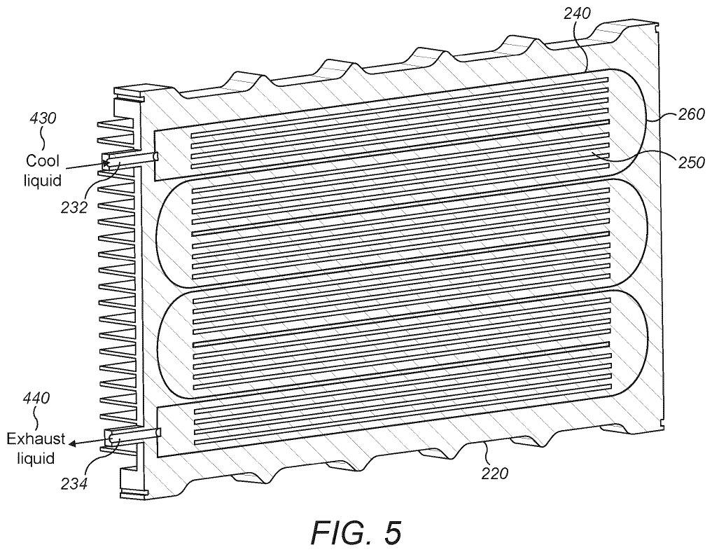

FIGS. 4 and 5 show views of a dual mode heatsink 200 according to a second embodiment. The heat generating object 100 is not shown in FIGS. 4 and 5. The dual mode heatsink 200 of the second embodiment is the same as the dual mode heatsink 200 of the first embodiment, except that the dual mode heatsink 200 of the second embodiment 200 has mounting structures 300 on the first surface 202 for mounting one or more heat generating objects, and also has connecting structures 310 on the second surface 204 for attaching the dual mode heatsink 200 to a supporting structure. The mounting structures 300 and connecting structures 310 are not essential, and may be omitted, as in the first embodiment, or take a different form, as required in any specific implementation.

FIG. 4 shows an end view of the dual mode heatsink 200 of the second embodiment. FIG. 5 shows a cut away view of the dual mode heatsink 200 of the second embodiment with the first surface 202 removed.

As shown in FIGS. 3 and 5, the base plate 220 contains a plurality of liquid flow channels 240 located between the first and second surfaces 202 and 204. The liquid flow channels 240 are defined between spaced apart walls 250 which extend between, and are integral with, the first and second surfaces 202 and 204. The walls 250 are each substantially flat and planar, are arranged parallel to one another, and extend perpendicularly to the first and second surfaces 202 and 204 of the base plate 220. As can be best seen in FIGS. 3 and 5, the walls 250 extend parallel to the cooling fins 210.

As shown in FIG. 5, the liquid flow channels 240 are arranged to form groups of multiple parallel liquid flow channels 240, in the illustrated embodiment groups of five parallel liquid flow channels 240. The groups of liquid channels 240 are connected together at their ends by manifold sections 260 to form a serpentine, or zig-zag, shaped set of liquid flow channels 240 covering most of the area of the base plate 220. The liquid flow channels 240 and the walls 250 are arranged within the base plate 220 in locations corresponding to the area of the second surface 204 where the cooling fins 210 are located, so that the walls 250 act as heat bridges thermally connecting the first surface 202 and the second surface 204, and can conduct heat energy from the heat generating object 100 to the cooling fins 210.

In the illustrated example of the first embodiment shown in FIG. 3, the cooling fins 210 are evenly spaced with a first pitch A, where the first pitch A is the distance between the centerlines of adjacent parallel cooling fins 210, and the walls 250 are also evenly spaced with a second pitch B, where the second pitch B is the distance between the centerlines of adjacent parallel walls 250. In the illustrated example, the first pitch A is double the second pitch B, and each cooling fin 210 is arranged to be aligned with a respective one of the parallel walls 250. Since the first pitch is double the second pitch, alternate ones of the parallel walls 250 are aligned with respective ones of the cooling fins 210.

In the illustrated example of FIG. 3, the cooling fins 210 are 2 mm wide and the gas flow channels 212 are 6 mm wide, so that the first pitch is 8 mm. Further, in this example, the walls 250 are 2 mm thick, and the liquid flow channels 240 are 2 mm wide, so that the second pitch is 4 mm. The height of the walls 250 and the liquid flow channels 240 is 3 mm.

It is not essential that the first pitch of the cooling fins 210 is equal to, or an integer multiple of, the second pitch of the walls 250, or that the cooling fins 210 are aligned with respective ones of the walls 250. However, such an arrangement may provide an advantage of better conduction of heat energy from the heat generating object 100 and through the walls 250 to the cooling fins 210, and may provide a physically stronger structure.

In the illustrated example of the second embodiment shown in FIG. 5, the cooling fins 210 are evenly spaced with a first pitch A, and the walls 250 are also evenly spaced with a second pitch B, and the first pitch A is greater than the second pitch B. However, in this example the first pitch is not an integer multiple of the second pitch. Accordingly, in the illustrated example of FIG. 5, the cooling fins 210 are not all aligned with parallel walls 250, although some of the cooling fins 210 may be aligned with a parallel wall 250. In the illustrated arrangement of FIG. 5 the first and second pitches are selected independently of one another. The first pitch of the cooling fins 210 is selected to maximize the efficiency of the gas cooling, and the second pitch of the walls 250 is selected to maximize the efficiency of the liquid cooling. In some examples such independent selection of the first and second pitches may provide an advantage of better cooling efficiency which outweighs any reduction in conduction of heat energy from the heat generating object 100 through the walls 250 to the cooling fins 210 resulting from the walls 250 and cooling fins 210 not being aligned.

In the illustrated example of FIG. 5, the cooling fins 210 are 2 mm wide and the gas flow channels 212 are 4 mm wide, so that the first pitch is 6 mm. Further, in this example, the walls 250 are 2 mm thick, and the liquid flow channels 240 are 2 mm wide, so that the second pitch is 4 mm. The height of the walls 250 and the liquid flow channels 240 is 3 mm.

It may be preferred that the height of the walls 250 and the liquid flow channels 240 is in the range 1 mm to 3 mm. Without wishing to be bound by theory, this may provide a good balance between the ease of manufacture of the base plate 220 comprising the liquid flow channels 240 and the height of the walls 250 and liquid flow channels 240 being low enough for the walls 250 to provide a good path for heat flow through the base plate 220.

Without wishing to be bound by theory, it is expected that it will generally be preferred for the first pitch of the cooling fins 210 to be greater than the second pitch of the walls 250, so that the gas flow channels 212 are wider than the liquid flow channels 240.

The dimensions given above are by way of example only, and different dimensions may be used. Without wishing to be bound by theory, it is expected that if the thickness of the walls 250 is too large, compared to the width of the liquid flow channels 240, the liquid cooling may be inefficient, but that is the thickness of the walls 250 is too small, compared to the width of the liquid flow channels 240, the conduction of heat to the cooling fins 210 may be poor, making the gas cooling inefficient. Accordingly, in any specific implementation an optimum ratio between the thickness of the walls 250 and the width of the liquid flow channels 240 may be determined.

It is not essential that the walls 250 extend parallel to the cooling fins 210. However, this may be advantageous to spread the heat energy from the heat generating object 100 across the full length of the cooling fins 210, to improve cooling efficiency in the first, gas-cooled, mode.

As shown in FIGS. 4 and 5, the heatsink 200 further comprises liquid openings 232 and 234 in a side surface of the base plate 220. The liquid openings 232 and 234 comprise a liquid inlet 232 and a liquid outlet 234. The liquid openings 232 and 234 are connected to the liquid flow channels 240. The liquid inlet 232 and liquid outlet 234 are arranged to allow liquid to flow through the liquid inlet 232 into the base plate 220 of the dual mode heatsink 200, through the serpentine shaped set of liquid flow channels 240, and through the liquid outlet 234 out of the base plate 220 of the dual mode heatsink 200. The arrangement of the liquid flow channels 240 into groups of parallel liquid flow channels 240 is not essential. However, this may reduce the flow resistance of a liquid flowing through the liquid flow channels, and so reduce the pressure drop of a flowing liquid between the liquid inlet 232 and the liquid outlet 234. Conveniently, the parts of the base plate 220 other than the liquid flow channels 240, manifold sections 260, and liquid inlet and outlet 232 and 234 may be solid between the first and second surfaces 202 and 204.

The illustrated examples have the walls 250 integrally formed with the base plate 220. Conveniently, these integrally formed walls 250 and base plate 220 can be formed by an additive manufacturing technique. In alternative examples, the liquid flow channels 240 can be formed by boring liquid flow channels 240 in a solid base plate 220, leaving the material of the walls 250 in place. In other alternative examples, the walls 250 and the base plate 220 can be manufactured as separate parts and subsequently attached together. In such alternative examples, the walls 250 can be attached to the first and second surfaces 202 and 204 of the base plate 220 of the heatsink 200 via welding or a heat conductive adhesive layer.

The cooling fins 210 and the gas flow channels 212 defined between each of the cooling fins 210 form a gas-cooling mechanism of the dual mode heatsink 200. The base plate 220 is arranged to transfer heat energy from the heat generating object 100 to the cooling fins 210 by conduction through the first surface 202 and the second surface 204 and the connecting parts of the base plate 220. In the region of the set of liquid channels 240 the heat energy can pass from the first surface 202 of the base plate 220 to the second surface 204 by conduction through the walls 250. The walls 250 form respective heat conducting connections between the first surface 202 and the second surface 204. Accordingly, the dimensions of the walls 250 must be selected to allow sufficient heat conduction between the first surface 202 and the second surface 204 to enable proper operation of the dual mode heat sink 200 in the first, gas cooled, mode. In particular, the spacing, thickness and height of the walls 250 must be appropriately selected. Without wishing to be bound by theory, it is expected that in practice it will be simplest to vary the thickness of the walls 250 to control the amount of heat conduction.

The liquid flow channels 240 defined between the walls 250 and the first and second surfaces 202 and 204 of the base plate 220 form a liquid cooling mechanism of the dual mode heatsink 200. The base plate 220 is arranged to transfer heat energy from the heat generating object 100 to the walls 250 by conduction through the first surface 202.

It might be expected that the presence of the liquid channels 240 and other elements of the liquid cooling mechanism within the base plate 220 would interfere with heat transfer through the base plate 220 between the heat source of the heat generating object 100 and the cooling fins 210 of the gas cooling mechanism. However, in practice it has been found that the area of the base plate 220 required by the liquid channels 240 and the area of the base plate 220 required by the walls are both relatively small, so that locating the liquid cooling mechanism within the base plate 220 does not interfere with operation of the gas cooling mechanism.

The dual mode heatsink 200 is able to operate in a first, gas-cooled mode using the gas-cooling mechanism, or in a second, liquid-cooled, mode using the liquid cooling mechanism. Accordingly, the same dual mode heatsink 200 may be used in both applications requiring gas cooling and applications requiring liquid cooling. This may reduce the number of different heat sink designs which must be maintained in inventory for use in manufacturing, repair, and maintenance tasks, reducing costs and simplifying logistics. Further, in implementations where the dual mode heatsink is provided integrally with a heat producing object which the heatsink is to cool, this may allow the same integrated heat producing object and heatsink assembly be used in both applications requiring gas cooling and applications requiring liquid cooling. This may reduce the number of different integrated assemblies which must be maintained in inventory for use in manufacturing, repair, and maintenance tasks, reducing costs and simplifying logistics. Further, by allowing the same dual mode heatsink or integrated assembly to be used in both applications requiring gas cooling and applications requiring liquid cooling the number of heatsink and integrated assembly designs which must be tested and certified may be reduced, which may reduce costs.

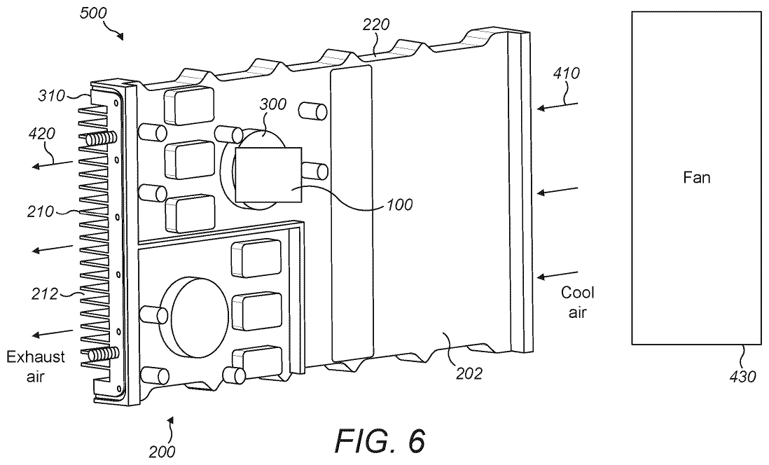

FIG. 6 shows a schematic diagram of the dual mode heatsink 200 comprised in a gas cooled temperature control system 500, and arranged to operate in the first, gas cooled, mode. The gas cooled temperature control system 500 comprises the dual mode heatsink 200, a heat generating object 100 in thermally conductive contact with the first surface 202 of the dual mode heatsink 200, and a gas flow generator fan 430.

When the dual mode heatsink 200 operates in the first, gas cooled, mode as part of the gas cooled temperature control system 500, the dual mode heatsink 200 cools the heat generating object 100, and so controls the temperature of the heat generating object 100, by absorbing heat energy from the heat generating object 100, and is cooled in turn by the heat energy being transferred to gas flows driven by the fan 430 through the gas flow channels 212 defined between each of the cooling fins 210. The gas flows into the gas flow channels 212 as a cool gas 410, flows past the cooling fins 210, absorbing heat energy from the cooling fins 210 and the second surface 204, and is exhausted from the gas flow channels 212 as a hot exhaust gas 420, so removing heat from the dual mode heatsink 200. Whilst the gas is passing through the gas flow channels 212 between the cooling fins 210, heat energy from the cooling fins 210 and the first surface 202 is absorbed by the gas and the movement of the flowing gas transports the heat away from the heatsink 200. Accordingly, the gas cooled temperature control system is able to control the temperature of the heat generating object 100 by transferring heat energy from the heat generating object 100 to the exhaust gas 420.

In the illustrated example of FIG. 6, the gas flows into and out of the gas flow channels 212 as a pumped flow driven by the fan 430 located upstream of the gas flow channels 212. In alternative examples, one or more fans 430 may alternatively, or additionally, be located downstream of the gas flow channels 212. In alternative arrangements, the fan 430 may be replaced by an alternative driver for a gas flow. For example, the fan 430 may be replaced by an external gas pump, or a pressurized gas reservoir arranged to release a gas flow. These examples are not intended to be exhaustive. In the illustrated example of FIG. 6 the cooling gas is air, but this is not essential, and other gasses may be used in alternative examples.

In other examples, instead of a driven gas flow driven by the fan 430, the gas cooled temperature control system 500 may be arranged to generate convection gas flows through the gas flow channels 212 driven by thermal expansion of the gas, or gas flows driven by ambient gas movement, without any external mechanism driving the gas flow. In examples where the cooling gas is air, ambient gas movement may be provided by the wind, or by movement of a vehicle comprising the gas cooled temperature control system 500 relative to the air.

In some examples, in addition to flowing through the gas flow channels 212, gas may also flow past and absorb heat energy from the cooling fins 210 located at the edges of the base plate 220.

When the dual mode heat sink 200 is to be used in a gas cooled temperature control system 500 the liquid flow channels 240 may be filled with a gas, filled with a liquid, or contain a vacuum, as desired in any specific implementation. In examples where the liquid flow channels 240 are filled with a gas and/or a liquid the liquid openings 232 and 234 may be sealed to retain the gas and/or liquid, and means (not shown) may be provided to allow for thermal expansion of the gas and/or liquid to prevent excessive pressure build up within the liquid flow channels due to thermal expansion when the heat generating object 100 is generating heat. It may be preferred for the liquid flow channels 240 to contain a liquid to keep the mass of the dual mode heat sink 200 the same in both operating modes. Further, it may be preferred for the liquid flow channels 240 to contain a liquid to improve the physical strength of the base plate 220. As is explained above, heat energy can pass from the first surface 202 of the base plate 220 to the second surface 204 by conduction through the walls 250, and, without wishing to be bound by theory, it is expected that the dual mode heat sink 200 will be designed to have sufficient thermal conductivity between the first and second surfaces 202 and 204 of the base plate 220 through the walls 250 and other solid parts of the base plate 220 without having to take into account heat energy passing through the liquid flow channels 240. However, in some examples it may be preferred to have gas and/or liquid within the liquid flow channels 240 to provide increased thermal conductivity. In some examples it may be preferred to leave the liquid openings 232 and 234 unsealed so that the liquid flow channels 240 are filled with air or vacuum, depending upon the ambient environment in which the dual mode heat sink 200 is located.

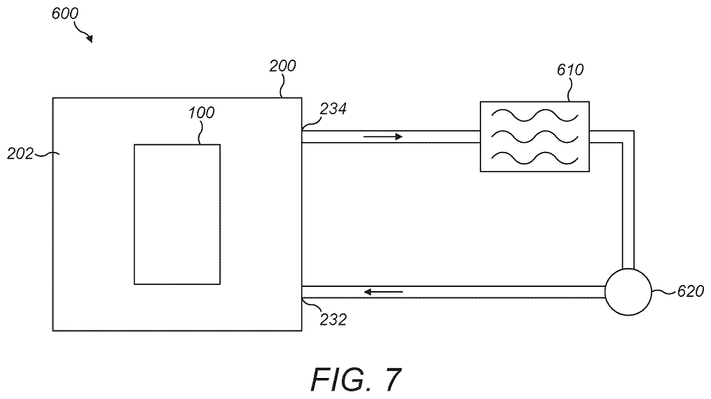

FIG. 7 shows a schematic diagram of the dual mode heatsink 200 comprised in a liquid cooled temperature control system 600, and arranged to operate in the second, liquid cooled mode. The liquid cooled temperature control system 600 comprises the dual mode heatsink 200, a heat generating object 100 in thermally conductive contact with the first surface 202 of the dual mode heatsink 200, and a liquid flow generator formed by a heat exchanger 610 in fluid flow connection between the liquid inlet 232 and the liquid outlet 234, and a liquid pump 620 arranged to pump liquid around a liquid flow circuit formed by the dual mode heatsink 200 and the heat exchanger 610. In the illustrated example the liquid is water. Other liquids may be used in alternative examples.

When the dual mode heatsink 200 operates in the second, liquid cooled, mode as part of the liquid cooled temperature control system 600, the dual mode heatsink 200 cools the heat generating object 100, and so controls the temperature of the heat generating object 100, by absorbing heat energy from the heat generating object 100, and is cooled in turn by the heat energy being transferred to cooling liquid moving through the liquid flow channels 240 from the liquid inlet 232 to the liquid outlet 324. As the cooling liquid passes through the liquid flow channels 240, heat energy from the first surface 202 of the base plate 220 and the walls 250 is transferred to the cooling liquid. The movement of the cooling liquid transports the heated cooling liquid out of the heatsink 200 via the liquid outlet 324 to the heat exchanger 610 where the cooling liquid is cooled by transferring heat energy to the external environment, such as the atmosphere. The cooled cooling liquid is then returned to the liquid inlet 232 of the dual mode heatsink 200. The flow of the cooling liquid around the fluid circuit between the dual mode heatsink 200 and the heat exchanger 610 and through the liquid flow channels 240 is driven by the pump 620.

In other examples, instead of a closed circuit flow of the cooling liquid, an open circuit arrangement can be used in which the cooling liquid flows through the dual mode heatsink 200, and is then discarded. In examples using such open circuit arrangements, the cooling liquid flow may be driven by pressure or gravity instead of being driven by a pump.

The dual mode heatsink 200 has dimensions and geometry selected so that the rate of transfer of heat energy from the dual mode heatsink 200 to the cooling gas or liquid (that is, the rate of removal of heat energy from attached heat source(s) and/or heat generating object(s)) is the same, or substantially the same, in the first, gas cooled, mode and in the second, liquid cooled, mode. This may provide advantages in allowing the dual mode heatsink to be used in the same way, for example to cool the same heat generating object(s) regardless of whether gas cooling of liquid cooling is required.

As an alternative to the examples of use of the dual mode heatsink 200 described above, where the dual mode heatsink 200 operates in either a first gas cooled mode, or a second liquid cooled mode, the dual mode heatsink could be arranged to operate using both gas cooling and liquid cooling simultaneously. Such simultaneous use of gas cooling and liquid cooling could be continuous, or could be selective based on heating requirements. In some examples, the dual mode heatsink 200 could be switched between using different ones, or both, of gas cooling and liquid cooling based on changing circumstances and/or cooling requirements.

In the illustrated examples the cooling fins 210 are a plurality of flat, parallel strips extending perpendicular to the second surface 204 of the base plate 220. However, this is by way of example only, and the cooling fins 210 are not limited to this geometry. The cooling fins 210 may be curved or serpentine to define curved or serpentine gas flow channels between them. Other shapes and forms of cooling fins may be used instead of, or in combination with, strips, such as pins and blocks, so long as the heat from the base plate 220 can be removed by gas flowing past the cooling fins 210. The surface area, materials, and surface texture of the cooling fins 210 can be adjusted to control a rate of cooling of the heat generating object 100.

In the illustrated examples the walls 250 are a plurality of flat, parallel strips extending perpendicular to the first and second surfaces 202 and 204 of the base plate 220. However, this is by way of example only, and the walls 250 are not limited to this geometry. The walls 250 may be curved or serpentine to define curved or serpentine liquid flow channels 240 between them. The surface area, materials, and surface texture of the walls 250 can be adjusted to control a rate of cooling of the heat generating object 100.

In the illustrated examples the liquid openings 230 are positioned on the same side surface of the base plate 220. However, this is not essential. The liquid openings 230 are not limited to being positioned on a side surface of the base plate 220, or to being on a same surface of the base plate 220. The liquid openings 230 can be positioned in any surface of the heatsink 200, provide that they are fluidly connected together by liquid flow channels having suitable geometry.

The heatsink 200 is made from a thermally conductive material or materials. The thermally conductive material may comprise aluminum, copper, alloys thereof, plastics materials, or any other material suitable for the conductive transfer of heat energy.

As is discussed above, the dual mode heatsink 200 can be manufactured using additive manufacturing techniques. This may advantageously allow the entire dual mode heatsink 200 including the cooling fins 210 and walls 250 to be integrally formed.

In the illustrated examples the walls 250 extend substantially parallel to the cooling fins 210. This may be advantageous to allow heat energy from the heat generating object 100 to be spread by conduction through the walls 250 across the full length of the cooling fins 210. However, it is not essential that the walls 250 are parallel to the cooling fins 210. In other examples, the walls 250 and the cooling fins 210 can extend in different directions. For example, the liquid tube 240 and cooling fins 210 can extend perpendicularly. In other examples, the cooling fins may have other shapes, such as pin fins, so that the cooling fins 210 do not have an overall direction.

In the illustrated examples the flow channels comprise groups of five parallel flow channels. This is not essential, and alternative examples may use a different number of parallel flow channels.

In the illustrated examples base plate comprises liquid flow channels 240 defined by the walls 250. In other examples, these flow channels may be fluid flow channels for a cooling fluid, such as a gas.

It will be understood that the benefits and advantages described above may relate to one embodiment or may relate to several embodiments. The embodiments are not limited to those that solve any or all of the stated problems or those that have any or all of the stated benefits and advantages. Variants should be considered to be included into the scope of the invention.

Any reference to ‘an’ item refers to one or more of those items. The term ‘comprising’ is used herein to mean including the method steps or elements identified, but that such steps or elements do not comprise an exclusive list and a method or apparatus may contain additional steps or elements.

Further, as used herein, the term “exemplary” is intended to mean “serving as an illustration or example of something”.

Further, to the extent that the term “includes” is used in either the detailed description or the claims, such term is intended to be inclusive in a manner similar to the term “comprising” as “comprising” is interpreted when employed as a transitional word in a claim.

The figures illustrate exemplary methods. While the methods are shown and described as being a series of acts that are performed in a particular sequence, it is to be understood and appreciated that the methods are not limited by the order of the sequence. For example, some acts can occur in a different order than what is described herein. In addition, an act can occur concurrently with another act. Further, in some instances, not all acts may be required to implement a method described herein.

The order of the steps of the methods described herein is exemplary, but the steps may be carried out in any suitable order, or simultaneously where appropriate. Additionally, steps may be added or substituted in, or individual steps may be deleted from any of the methods without departing from the scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims.

What is claimed is:

1. A dual mode heatsink comprising:
a base comprising a first surface configured to receive heat energy from a heat source and a second surface; and
cooling fins extending from the second surface;
wherein the base further comprises at least one liquid channel arranged between the first surface and the second surface, the at least one liquid channel defined by one or more walls forming a heat conducting connection between the first surface and the second surface.

2. The dual mode heatsink of claim 1, wherein the cooling fins define gas flow channels between them.

3. The dual mode heatsink of claim 1, wherein:
the cooling fins are located across an area of the second surface; and
the at least one liquid channel and the one or more walls are arranged within the base at locations corresponding to the area of the second surface.

4. The dual mode heatsink of claim 1, wherein:
the cooling fins comprise a plurality of parallel fins; and
the one or more walls extend parallel to the fins.

5. The dual mode heatsink of claim 4, wherein:
the one or more walls comprise a plurality of walls;
the cooling fins have a pitch equal to, or an integer multiple of, a pitch of the walls; and
each cooling fin is aligned with a respective wall.

6. The dual mode heatsink of claim 1, wherein the dual mode heatsink is configured to be operable in:
a first, gas-cooled mode in which heat energy is transferred from the dual mode heatsink to gas flowing past the cooling fins; or
a second, liquid-cooled mode in which heat energy is transferred from the dual mode heatsink to liquid flowing through the at least one liquid channel; and
wherein a rate of heat transfer to the gas in the first, gas-cooled mode is substantially the same as a rate of heat transfer to the liquid in the second, liquid-cooled mode.

7. The dual mode heatsink according to claim 1, wherein the at least one liquid channel comprises a plurality of parallel liquid channels.

8. The dual mode heatsink according to claim 1, wherein the base and the cooling fins are integrally formed.

9. The dual mode heatsink according to claim 1, wherein the one or more walls and the first and second surfaces of the base are integrally formed.

10. The dual mode heatsink according to claim 1, wherein the dual mode heatsink is produced by additive manufacturing.

11. The dual mode heatsink according to claim 1, wherein the base and the cooling fins comprise aluminum, copper, or alloys thereof.

12. A temperature control system comprising:
a dual mode heatsink comprising:
a base comprising a first surface and a second surface; and
cooling fins extending from the second surface;
wherein the base further comprises at least one liquid channel arranged between the first surface and the second surface, the at least one liquid channel defined by one or more walls forming a heat conducting connection between the first surface and the second surface;
a heat source in thermal contact with the first surface; and
at least one of:
a gas flow generator configured to produce a gas flow past the cooling fins; or
a liquid flow generator configured to produce a liquid flow through the at least one liquid channel.

13. The temperature control system according to claim 12, wherein the temperature control system comprises either:
the gas flow generator; or
the liquid flow generator.

14. The temperature control system of claim 12, wherein the dual mode heatsink is configured so that a rate of heat transfer to the gas flow is substantially the same as a rate of heat transfer to the liquid flow.

15. The temperature control system according to claim 12, wherein the gas flow generator comprises a fan.

16. The temperature control system according to claim 12, wherein the gas flow comprises air.

17. The temperature control system according to claim 12, wherein the liquid flow generator comprises a pump and a heat exchanger.

18. The temperature control system according to claim 12, wherein the liquid flow comprises water.

19. A method of cooling a heat source, the method comprising:
providing a dual mode heatsink comprising:
a base comprising a first surface and a second surface; and
cooling fins extending from the second surface;
wherein the base further comprises at least one liquid channel arranged between the first surface and the second surface, the at least one liquid channel defined by one or more walls forming a heat conducting connection between the first surface and the second surface;
arranging the first surface of the dual mode heatsink in contact with a heat source; and
providing at least one of:
a gas flow past the cooling fins; or
a liquid flow through the at least one liquid channel.

20. The method of claim 19, wherein the method comprises either:
providing the gas flow past the cooling fins; or
providing the liquid flow through the at least one liquid channel.
